(19) United States
(12) Patent Application Publication
(10) Pub. No.: US 2010/0136821 A1
(43) Pub. Date: Jun. 3, 2010

(54) Connector terminal and method for making the same

(76) Inventors: Sheng-Yuan Huang, Tu-Cheng City (TW); Yung-Chi Peng, Tu-Cheng City (TW); Sheng-Nan Yu, Tu-Cheng City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/292,869

(22) Filed: Nov. 28, 2008

(51) Int. Cl. H01R 4/26; H05K 3/00

(52) U.S. Cl. 439/422; 29/829

(57) ABSTRACT

A connector terminal mounted in a flexible printed circuit board connector for electrically connecting with the flexible printed circuit board includes a fixing portion of strip shape, a soldering portion connecting with one end of the fixing portion and a contacting portion extending upwards from the other end of the fixing portion to show an arc shape. The contacting portion has a retaining portion protruding from a peak thereof. The retaining portion includes a smooth contacting surface for contacting the flexible printed circuit board and an end surface defined at one end thereof. The contacting surface and the end surface define a sharp junction therebetween. A peak of the sharp junction is capable of interfering with the flexible printed circuit board.

### BACKGROUND OF THE INVENTION

1. Field of the Invention

The present invention relates to a connector terminal applied in a flexible printed circuit board connector, and particularly to a method for making the same.

2. The Related Art

A flexible printed circuit (FPC) board connector is electrically connected with a FPC board via connector terminals thereof. FIG. 1 is a perspective view showing a connector terminal 20 of the FPC board connector in prior art. The connector terminal 20 includes a fixing portion 21, a soldering portion 22 and a contacting portion 23. The soldering portion 22 is bent downwardly from one end of the fixing portion 21 and then extended opposite to the fixing portion 21 to be parallel to the fixing portion 21. The contacting portion 23 is extended obliquely and upwards, and then bent downwardly to show an arc shape. The contacting portion 23 is disposed to elastically exceed out of an insulating housing of the FPC board connector for electrically connecting with the FPC board.

However, the contacting portion 23 of the presented connector terminal 20 can not keep steady connection with the FPC board because of inadequate retention force between the contacting portion 23 and the FPC board, when the FPC board connector is shaken and the like. So there is a need to increase retention force between the contacting portion 23 and the FPC board for achieving reliable connection between the FPC board connector and the FPC board.

### SUMMARY OF THE INVENTION

Accordingly, an object of the present invention is to provide a connector terminal having a structure which is capable of increasing retention force between the connector terminal and a flexible printed circuit (FPC) board. The connector terminal includes a fixing portion of strip shape, a soldering portion connecting with one end of the fixing portion and a contacting portion extending upwards from the other end of the fixing portion to show an arc shape. The contacting portion has a retaining portion protruding from a peak thereof. The retaining portion includes a smooth contacting surface for contacting the FPC board and an end surface defined at an end thereof. The contacting surface and the end surface define a sharp junction therebetween. A peak of the sharp junction is capable of interfering with the FPC board.

Another object of the present invention is to provide a method for making a connector terminal including the steps of:
a. punching a portion of a metal plate strip to form a protruding portion;
b. punching one end of the protruding portion in opposition to the protruding direction of the protruding portion to make the end of the protruding portion recover to a substantially original state in order to form a retaining portion at the other end of the protruding portion; and
c. bending the metal plate strip with the retaining portion to form the connector terminal having an arc-shaped contacting portion with the retaining portion disposed at a peak thereof.

As described above, the retaining portion disposed at the peak of the contacting portion has the sharp junction formed at a head thereof and consequently, the peak of the sharp junction can be against the FPC board to enhance the retention force therebetween for restraining the FPC board from sliding out of the FPC board connector. In addition, the method for making the connector terminal, which is simple, is apt to be used widely and suitable for mass production.

### BRIEF DESCRIPTION OF THE DRAWINGS

The present invention will be apparent to those skilled in the art by reading the following description of an embodiment thereof, with reference to the attached drawings, in which:

FIG. 1 is a perspective view of a connector terminal of the prior art;

FIG. 2 is a perspective view of a connector terminal of an embodiment according to the present invention;

FIG. 3 is a partly enlarged view showing an enlarged III portion of FIG. 2;

FIG. 4 is a perspective view illustrating state of making the connector terminal shown in FIG. 2 in the first step;

FIG. 5 is a partly enlarged view showing an enlarged V portion of FIG. 4;

FIG. 6 is a perspective view illustrating state of making the connector terminal shown in FIG. 2 in the second step;

FIG. 7 is a perspective view illustrating an example of the connector terminal of FIG. 2 mounted in a flexible printed circuit board connector; and

FIG. 8 is a cross-sectional view showing state of the connector terminal mounted in the flexible printed circuit board connector connecting with a flexible printed circuit board.

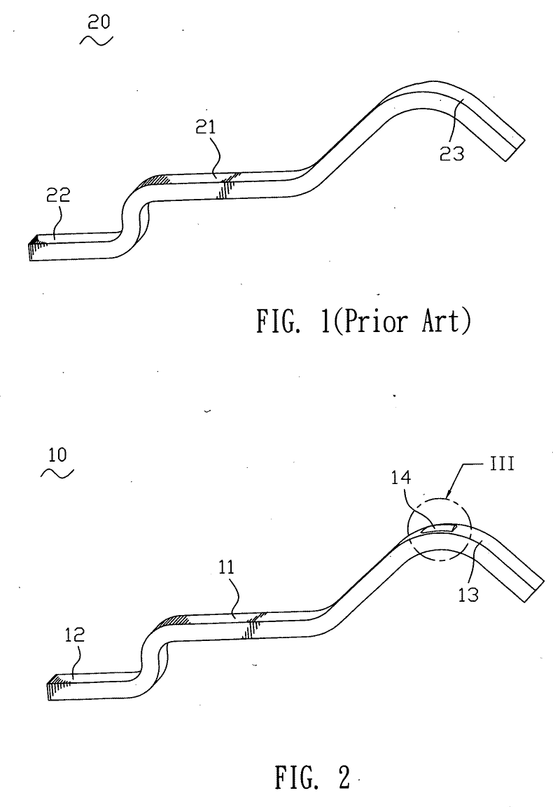

### DETAILED DESCRIPTION OF THE PREFERRED EMBODIMENT

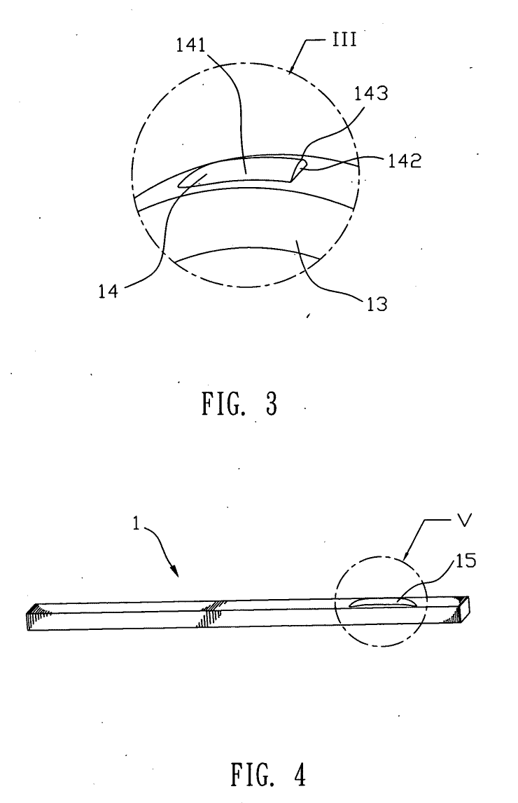

With reference to FIG. 2 and FIG. 3, an embodiment of a connector terminal 10 according to the present invention is shown. The connector terminal 10, which may be made of metal plate, has a fixing portion 11. The fixing portion 11 is a strip shape. One end of the fixing portion 11 is bent downwardly and then extended opposite to the fixing portion 11 to form a soldering portion 12. The soldering portion 12 is substantially parallel to the fixing portion 11 and adapted for being soldered on a printed circuit board (PCB). The other end of the fixing portion 11 is extended obliquely and upwards, and then bent downwardly to form a contacting portion 13. The contacting portion 13 is an arc-shape and has a retaining portion 14 at a top thereof. The retaining portion 14 is a substantially arc shape and includes a smooth contacting surface 141 extending curvedly and upwards, and an end surface 142 disposed vertically and connecting with the contacting surface 141 to form a sharp junction 143 therebetween. The sharp junction 143 is disposed at a head of the retaining portion 14 and against a flexible printed circuit board (FPC board for short, not shown).

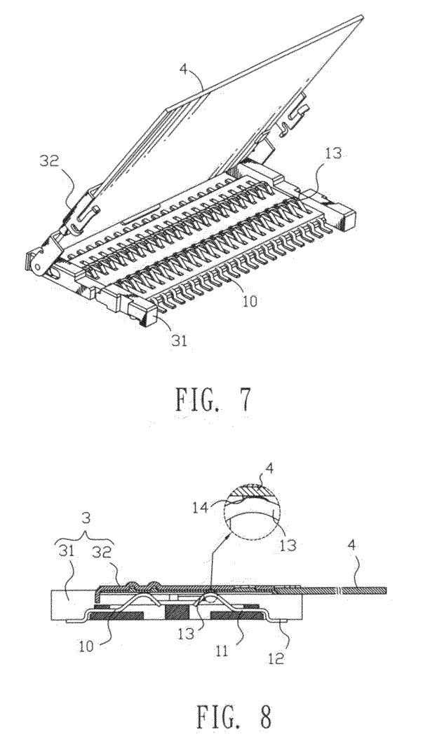

Referring to FIG. 7 and FIG. 8, the connector terminal 10 is mounted in an FPC board connector 3. An FPC board 4 is inserted into the FPC board connector 3 and then a cover 32 of the FPC board connector 3 is rotated to be coupled with an insulating housing 31 of the FPC board connector 3, thus the FPC board 4 is pressed downwardly to electrically connect with the connector terminals 10. Because the sharp junction 143 is disposed at a peak of the connector terminal 10, which will interfere with the FPC board 4 to enhance the retention force between the contacting portion 13 and the FPC board 4 for preventing the FPC board 4 from sliding out of the FPC board connector 3, so that the contacting portion 13 can connect with the FPC board 4 steadily.

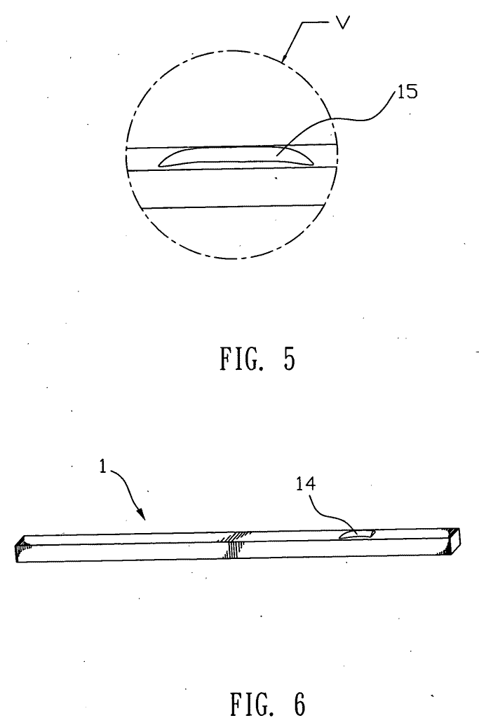

Please refer to FIGS. 4-6, a method for making the connector terminal 10 will be explained. In the first step, a metal plate strip 1 has a portion punched upwards to form a protruding portion 15 of convex and strip shape. In the second step, the protruding portion 15 is punched vertically and downwardly at one end thereof to a substantially original state so as to form the retaining portion 14 at the other end thereof, with the sharp junction 143 formed at a head of retaining portion 14. In the third step, the metal plate strip 1 with the retaining portion 14 is bent to form the connector terminal 10 having the arc-shaped contacting portion 13 with the retaining portion 14 disposed at a peak thereof.

As described above, the retaining portion 14 disposed at the peak of the contacting portion 13 has the sharp junction 143 formed at the head thereof and consequently, the peak of the sharp junction 143 can be against the FPC board 4 to enhance the retention force therebetween for restraining the FPC board 4 from sliding out of the FPC board connector 3. In addition, the method for making the connector terminal 10, which is simple, is apt to be used widely and suitable for mass production.

The foregoing description of the present invention has been presented for purposes of illustration and description. It is not intended to be exhaustive or to limit the invention to the precise form disclosed, and obviously many modifications and variations are possible in light of the above teaching. Such modifications and variations that may be apparent to those skilled in the art are intended to be included within the scope of this invention as defined by the accompanying claims.

What is claimed is:

1. A connector terminal mounted in a flexible printed circuit board connector for electrically connecting with a flexible printed circuit board, comprising:
a fixing portion of strip shape;
a soldering portion connecting with one end of the fixing portion; and
a contacting portion extending upwards from the other end of the fixing portion to show an arc shape, the contacting portion having a retaining portion protruding from a peak thereof, the retaining portion including a smooth contacting surface for contacting the flexible printed circuit board and an end surface defined at one end thereof, the contacting surface and the end surface defining a sharp junction therebetween, a peak of the sharp junction capable of interfering with the flexible printed circuit board.

2. A method for making a connector terminal as claimed in claim 1, comprising steps of:
a. punching a portion of a metal plate strip to form a protruding portion;
b. punching one end of the protruding portion in a direction towards the metal plate strip to form a retaining portion of a substantially arc shape; and
c. bending the metal plate strip with the retaining portion to form the connector terminal having an arc-shaped contacting portion with the retaining portion disposed at a peak thereof.
